(19) United States
(12) Patent Application Publication
(10) Pub. No.: US 2015/0307360 A1
(43) Pub. Date: Oct. 29, 2015

(54) NOVEL SOLUTION FOR ELECTROPHORETIC DEPOSITION OF NANOPARTICLES INTO THIN FILMS

(71) Applicant: SOUTH DAKOTA STATE UNIVERSITY, Brookings, SD (US)

(72) Inventors: Braden Bills, Sioux Falls, SD (US); Qi Hua Fan, Ann Arbor, MI (US)

(73) Assignee: SOUTH DAKOTA STATE UNIVERSITY, Brookings, SD (US)

(21) Appl. No.: 14/530,752

(22) Filed: Nov. 1, 2014

Related U.S. Application Data
(60) Provisional application No. 61/898,972, filed on Nov. 1, 2013.

(51) Int. Cl. C01B 33/02; C25D 13/02

(52) U.S. Cl. CPC C01B 33/02; C25D 13/02

(57) ABSTRACT

The present invention describes a non-aqueous organic solution for Electrophoretic Deposition (EPD) of nanoparticles onto thin films, including method of using said non-aqueous organic solution and EPD to produce films containing such nanoparticles for use in LED devices, Li ion batteries, as solar absorbers, and as thin film transistors.

### CROSS REFERENCE TO RELATED APPLICATION

This application claims benefit under 35 U.S.C. §119(e) to U.S. Provisional Application No. 61/898,972, filed Nov. 1, 2013, which is incorporated by reference herein in its entirety.

### BACKGROUND OF THE INVENTION

1. Field of the Invention

The present invention relates generally to deposition of nanoparticles onto substrates, and specifically to organic solutions for Electrophoretic Deposition (EPD) of nanoparticles containing semiconductor, metals, oxides and the like, onto thin films, including methods of using said organic solution and EPD to produce films containing such nanoparticles.

2. Background Information

Emerging research in nanotechnology has led to the development of nanomaterials such as nanoparticles, nanotubes, nanofibers and other structures. The application of these nanostructured materials for certain devices requires deposition of these materials as a film onto a substrate. Device performance largely depends on the quality of the deposited thin film such as its uniformity, adhesion to an underlying substrate and thickness. Various processes have been explored to obtain thin films of nanomaterials such as sol-gel electrochemical deposition, electrophoretic deposition and vacuum based growth techniques.

Electrophoretic deposition (EPD) has recently gained increasing interest in the processing of advanced ceramic materials and coatings. EPD has the advantages of short formation time, simple deposition apparatus, low cost, flexibility in shape and size of the substrates and suitability for mass production. EPD may be used for the fabrication of advanced ceramics in the form of thick or thin coatings laminates, including providing high quality nanoparticle films which exhibit strong adhesion to the underlying substrate, dense nanoparticle packing and uniform morphology.

Although EPD has been frequently performed in aqueous solutions, there is a deviation in the deposition kinetics from linear Hamaker growth due to deviation in current density and powder concentration. Further, electrolysis of water occurs at low voltages, and gas evolution causes bubbles to be trapped with the deposition. Moreover, when metallic electrode materials are used, the normal potential of the electrode is largely over-passed. This facilitates oxidation of the electrodes and migration of metallic impurities toward the slurry in the opposite direction of the migrating particles, which impurities may be retained in the deposit as heterogeneities, thus degrading film properties. To overcome these issues, additives may be included (e.g., charge agents), which additives add to the cost of using EPD.

In general, organic liquids are superior to water as a suspension medium for EPD. However, the stability of an organic suspension is often limited due in part to the dielectric constants of the organic liquid and the conductivity of the suspension. For example, for organic liquids with low dielectric constants, deposition may fail because of insufficient dissociative power, while organic liquids with high dielectric constants may reduce electrophoretic mobility of the nanoparticles, including that in order to achieve the highest possible green density with organic liquids having high dielectric constants, addition of binders (e.g., nitrocellulose) and charging agents (e.g., acids and bases) may be necessary, again, adding to the cost of using the method.

What is needed is a deposition solution that avoids producing suspensions exhibiting particle agglomeration, but does not form suspensions so stable that repulsive forces between nanoparticles will not be overcome by an applied electric field.

### SUMMARY OF THE INVENTION

The present invention relates to a stable nanoparticle suspension, which suspension contains a non-aqueous solution, where the suspension does not require salts or ionic surfactants to achieve high quality electronic films using EPD.

In one embodiment, a composition is disclosed consisting essentially of an organic solvent including an aprotic, non-polar organic solvent; a protic, polar organic solvent; a ketone or a combination thereof; and a plurality of nanoparticles, where the plurality of nanoparticles comprise an elemental semiconductor, alloyed semiconductor, or oxide.

In one aspect, the elemental semiconductor is Si or Ge.

In another aspect, the aprotic, non-polar solvent has the general structure as set forth in Formula I:

(CₙH₂ₙ₊₂₋₂ᵣ) (Formula I),
where n is an integer from 6 to 20, and r, the number of ring structures, is an integer from 0 to 3,
and where the protic, polar organic solvent has the general structure as set forth in Formula II:

(CₙH₂ₙ₊₂₋ₘ₋₂ᵣ(OH)ₘ) (Formula II),

where n is an integer from 1 to 20, m is an integer from 1 to 10, and r, the number of ring structures, is an integer from 0-3, and where the ketone organic solvent has the general structure as set forth in Formula III:

(CnH₂₊₂₋₂ᵣ(C═O)ₘ) (Formula III),

where n is an integer from 1 to 30, m is an integer from 1 to 5 and r, the number of ring structures, is an integer from 0 to 3.

In a related aspect, the aprotic, non-polar organic solvent is an alkane and exhibits a dielectric constant of less than about 10. In another aspect, the protic, polar organic solvent is selected from the group consisting of methanol, ethanol, propanol, butanol, pentanol, hexanol, heptanol, octanol, nonanol, and decanol.

In a further aspect, the ketone is symmetrical, asymmetrical, a di-ketone, an unsaturated ketone, or a cyclic ketone.

In one aspect, the organic solvent includes decane and hexanol. In another aspect, the organic solvent includes hexanol and acetone.

In one embodiment, a method of depositing a plurality of Si or Ge nanoparticles on a substrate is disclosed including adding the composition as described above to a vessel; placing two electrodes into the composition, whereby said electrodes serve as an anode and a cathode in electric communication with a power supply, and wherein at least one of the electrodes comprises the substrate; and applying voltage across the electrodes for a sufficient time to coat said substrate with the Si or Ge nanoparticles.

In a related aspect, the ratio of an aprotic, non-polar organic solvent to a protic, polar organic solvent is about 95:5, or wherein the ratio of ketone to protic, polar organic solvent is 1:1, and wherein the plurality of Si nanoparticles are present at between about 0.00005 g/mL to about 0.5 g/mL.

In a further related aspect, the method further includes re-crystallizing the Si or Ge nanoparticles by photonic curing.

In a further related aspect, the aprotic, non-polar organic solvent is an alkane and exhibits a dielectric constant of less than about 10.

In one aspect, the protic, polar organic solvent is selected from the group consisting of methanol, ethanol, propanol, butanol, pentanol, hexanol, heptanol, octanol, nonanol, and decanol. In another aspect, the ketone is symmetrical, asymmetrical, a di-ketone, an unsaturated ketone, or a cyclic ketone.

In a further aspect, the organic solvent comprises decane and hexanol. In another aspect, the organic solvent comprises hexanol and acetone.

In another embodiment, a Si or Ge nanoparticle-based film produced by the method as described above is disclosed. In one aspect, a surface of the film comprising the nanoparticles is devoid of agglomerations. In a related aspect, the agglomerations include clumps of nanoparticles>about 2× or 3× the diameter of a single nanoparticle in an area of about 15 μm×10 μm at a magnification of 10K as visualized under a scanning electron microscope (SEM). In a further related aspect, the agglomerations have a diameter of between about 2 nm to about 500 nm.

### BRIEF DESCRIPTION OF THE DRAWINGS

FIG. 1 shows Raman spectra of Si wafer, Si powder, EPD as-deposited Si nanoparticles, and flash lamp treated Si nanoparticles.

FIG. 2 shows production of nanoparticle-based film by electrophoretic deposition (EPD).

FIG. 3 shows the expected mechanism of stabilization of Si nanoparticles in non-aqueous solution.

FIG. 4 shows low temperature growth scheme of mc-Si film from Si nanoparticles.

FIG. 5 shows an illustration of water splitting for on-demand hydrogen fuel generation.

FIG. 6 shows an illustration of a Si anode for Li ion battery.

FIG. 7 shows photoluminescence of Si nanoparticles (left) and photon downshifting in solar cell with Si nanoparticle layer (right).

FIG. 8 shows SEM images of Si nanoparticle based film on ITO coated glass.

FIG. 9 shows SEM images of as-deposited Si nanoparticle-based films at different applied voltages.

FIG. 10 shows a diagram of a three step process for producing re-crystallized microcrystalline Si thin films by (1) stabilizing Si nanoparticles in solution; (2) producing Si nanoparticle-based films by EPD); and (3) re-crystallizing Si nanoparticle-based films by photonic curing.

FIG. 11 shows Raman spectra of Si nanoparticle-based film on ITO substrate produced (a) without photonic cure, (b) with low-energy photonic cure, and (c) with high-energy photonic cure.

### DETAILED DESCRIPTION OF THE INVENTION

Before the present composition, methods, and methodologies are described, it is to be understood that this invention is not limited to particular compositions, methods, and experimental conditions described, as such compositions, methods, and conditions may vary. It is also to be understood that the terminology used herein is for purposes of describing particular embodiments only, and is not intended to be limiting, since the scope of the present invention will be limited only in the appended claims.

As used in this specification and the appended claims, the singular forms “a”, “an”, and “the” include plural references unless the context clearly dictates otherwise. Thus, for example, references to “a nanoparticle” includes one or more nanoparticles, and/or compositions of the type described herein which will become apparent to those persons skilled in the art upon reading this disclosure and so forth.

Unless defined otherwise, all technical and scientific terms used herein have the same meaning as commonly understood by one of ordinary skill in the art to which this invention belongs. Any methods and materials similar or equivalent to those described herein can be used in the practice or testing of the invention, as it will be understood that modifications and variations are encompassed within the spirit and scope of the instant disclosure.

As used herein, “consisting essentially of” means the specified ingredients recited and those that do not materially affect the basic and novel characteristics of the composition.

As used herein, “about,” “approximately,” “substantially” and “significantly” will be understood by a person of ordinary skill in the art and will vary in some extent depending on the context in which they are used. If there are uses of the term which are not clear to persons of ordinary skill in the art given the context in which it is used, “about” and “approximately” will mean plus or minus <10% of particular term and “substantially” and “significantly” will mean plus or minus >10% of the particular term. Other terms such as “consisting” or “consisting essentially of” may be used to describe the products as disclosed herein.

As used herein, “photonic curing” is a high-temperature thermal processing of a thin film using pulsed light from a flashlamp. When this transient processing is done on a low-temperature substrate such as plastic or paper, it is possible to attain a significantly higher temperature than the substrate can ordinarily withstand under an equilibrium heating source such as an oven. Since the rate of most thermal curing processes (drying, sintering, reacting, annealing, etc.) generally increase exponentially with temperature (i.e., they obey the Arrhenius equation), this process allows materials to be cured much more rapidly (in about 1 millisecond) than with an oven, which can take minutes. In embodiments, nanoparticle-based films may be photonic cured using a Novacentrix PulseForge system (Austin, Tex.). The photonic curing process may include pre-heating a sample and using flash lamp pulsing to produce an effective amount of energy (e.g., 4500 to 7500 mJ/cm²) to process the thin films.

Si nanoparticles films are increasing in interest recently for their high surface area to volume ratio, quantum properties, and re-crystallization potential. For example, applications of Si nanoparticle films include, but are not limited to, Li ion battery electrodes, spontaneous hydrogen generation, photon downshifting for solid state lighting and solar cells, quantum energy devices and re-crystallized microcrystalline Si.

Flat panel displays with microcrystalline Si thin film transistors (TFTs), for example, can achieve higher display brightness and faster dynamic response while consuming less power compared to amorphous Si TFTs. Microcrystalline Si may be used as the bottom sub-cell of multi-junction thin film Si solar cells to absorb low energy (red) light and can improve the stability and efficiency of the solar cell.

At present, there is no efficient method to rapidly produce large area mc-Si thin films at low temperatures. For example, PECVD process conditions (silane/hydrogen ratio) tend to be very slow. Crystallizing amorphous Si (a-Si) by high-temperature (600-1000° C.) vacuum annealing is energy intensive and cannot be used with low cost substrates (e.g. glass, polymers). Alternatively, while crystallizing amorphous-Si by scanning laser annealing can be used at low-temperature, it is also slow and limited to small areas. Crystallizing amorphous-Si by photonic curing (flash lamp) has also been attempted, however, crystal size is too small (<0.5 μm) for use, and re-crystallizing Si nanoparticles (5 nm) with laser annealing gives poor uniformity and density of nanoparticle film, resulting in inconclusive re-crystallization results.

In embodiments, a stable Si nanoparticle suspension has been developed. In one aspect, depositing high quality Si nanoparticle-based films using the suspension and an electrophoretic deposition method is disclosed herein. In another aspect, re-crystallizing Si nanoparticle-based film using a rapid, large area and low temperature method to produce microcrystalline Si thin films on low cost substrates such as glass is disclosed herein.

It is art recognized that high quality nanoparticle-based films require stable particle suspensions. However, no known stable suspensions for Si or Ge nanoparticles exist. In the present disclosure, a non-aqueous solution has been developed without the use of salts or ionic surfactants to subsequently achieve high quality electronic films after re-crystallization. In one aspect, a high stability (hours) of Si or Ge nanoparticles is achieved.

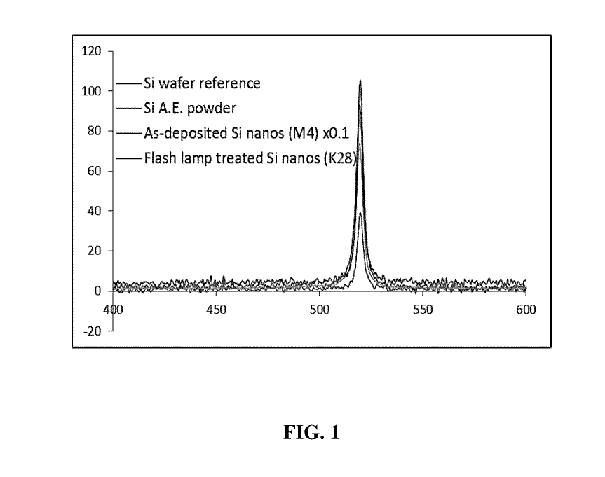

As disclosed herein, Si nanoparticles were electrophoretic deposited into films with high uniformity and density. In one aspect, photonic curing is a suitable method to selectively crystallize light absorbing thin films without exceeding the substrate melting temperature, although other methods such as laser or thermal annealing may be used. In embodiments, photonic curing using, for example, a Novacentrix PulseForge system showed that Si nanoparticles were able to be re-crystallized (confirmed with Raman spectroscopy; FIG. 1).

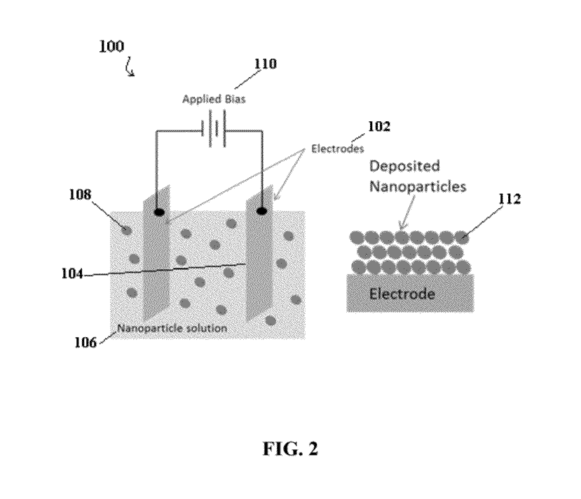

In embodiments, methods are described which include exposing a substrate to a solution comprising nanoparticles and applying an electric field to the solution, whereby a nanoparticle film is deposited on the substrate via electrophoretic deposition (EPD). An exemplary apparatus 100 for carrying out an embodiment of such methods is shown in FIG. 2. An electrode 102 and a substrate 104 acting as a counter electrode are exposed to a solution 106 comprising dispersed nanoparticles 108. An electric field is applied to the solution using a power supply 110. Under the influence of the electric field, the nanoparticles 108 are transported to the substrate 104, where they deposit to form a densely-packed film 112.

In embodiments, organic alkanes may be used as solution media, as such solutions prevent electrochemical reactions (i.e., bubbles) from occurring at the electrodes with applied voltage. As noted above, bubbles prevent deposition of nanoparticle based films.

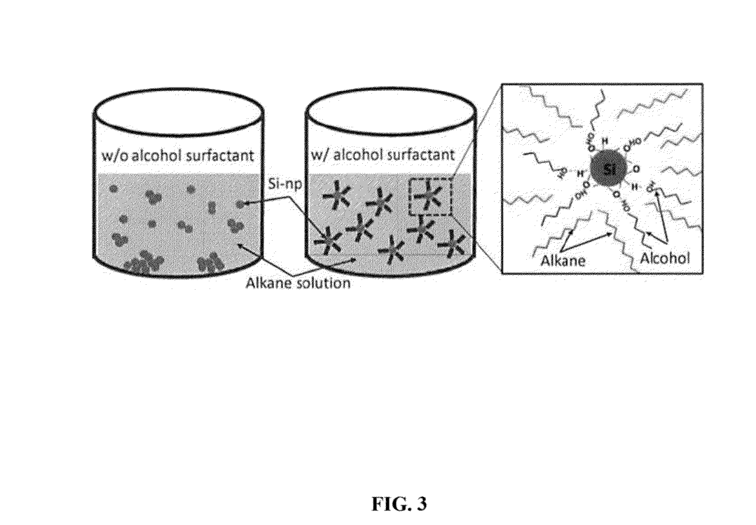

While not being bound by theory, the expected mechanism of stabilization of Si nanoparticles involves the formation of reverse micelles around the oxidized Si nanoparticles, thereby stabilizing the particles in the organic solution. For example, as shown in FIG. 3, the illustration on the left shows oxidized Si nanoparticles suspended in a non-polar, aprotic organic solvent (e.g., straight chain alkane) in the absence of a polar, protic organic solvent (e.g., a straight chain monoalcohol). In this example, stability is poor, i.e., nanoparticles only remain suspended for a few minutes before agglomeration occurs due to Brownian motion. As particles agglomerate, they settle to the bottom as Si nanoparticles where polar oxidized surfaces are not stable in the non-polar, aprotic organic solvent.

For the middle illustration of FIG. 3, the addition of a polar, protic organic solvent (e.g., hexanol) acts as a surfactant which allows for the formation of reverse micelles around the oxidized Si nanoparticles, thereby stabilizing the nanoparticles in solution. Again, while not being bound by theory, the structure of the reverse micelles is shown on the right illustration of FIG. 3, where the hydroxyl groups of the alcohol hydrogen bonds to the surface oxide of the nanoparticle and the aliphatic chain of the alcohol forms van der Waal's bonds with the aliphatic groups of the alkane, thereby Brownian motion is reduced and agglomeration minimized. In embodiments, the non-polar, aprotic organic solvent/polar, protic organic solvent suspension as disclosed improves stability of a nanoparticle suspension from a few minutes to a few hours.

### Solutions

The solutions for use in the disclosed methods comprise nanoparticles, a non-polar, aprotic organic solvent and a polar, protic organic solvent. Each of these components is further described below.

In embodiments, straight chain or branched chain alkanes (or combinations thereof) may be used in the solutions as disclosed, including, but not limited to those alkanes containing isopropyl, isobutyl, sec-butyl radicals at terminal positions. In embodiments, the non-polar, aprotic organic solvent may be a straight chain (normal) alkane having the general formula (Formula I):

(CₙH₂ₙ₊₂) Formula I,

wherein n is an integer from 6 to 20, and where the alkane exhibits a dielectric constant of less than about 10. In one aspect, alkanes include, but are not limited to, hexane, heptane, octane, nonane, decane, undecane, dodecane, tetradecane, pentadecane, and eicosane. In a related aspect, the alkane is decane.

In embodiments, the polar, protic organic solvent may be a straight chain alcohol having the general formula (Formula II):

(CₙH₂ₙ₊₂₋ₘ(OH)ₘ) (Formula II)

wherein n is an integer from 1 to 20 and m is an integer from 1 to 10.

In one aspect, alcohols include, but are not limited to, methanol, ethanol, propanol, butanol, pentanol, hexanol, heptanol, octanol, nonanol, and decanol. In a related aspect, the alcohol is hexanol.

In embodiments, the ketone organic solvent has the general structure as set forth in Formula III:

(CnH₂ₙ₊₂₋₂ᵣ(C═O)ₘ) (Formula III),

wherein n is an integer from 1 to 30, m is an integer from 1 to 5 and r, the number of ring structures, is an integer from 0 to 3.

In one aspect, the ketone organic solvents include, but are not limited to, acetone, methyl ethyl ketone, cyclohexanone, methyl propyl ketone, propyl acetone, amyl methyl ketone, hexyl methyl ketone, and octyl methyl ketone.

In embodiments, the alkane to alcohol ratio may be about 95:5, about 96:4, about 97:3, about 98:2 or about 99:1. In one aspect, the ratio is about 95:5. In other embodiments, the ketone to alcohol ratios may be about 1:1, about 2:1 or about 1:2.

In embodiments, the solutions as recited herein may be used for electronic material grade applications.

### Nanoparticles

Solutions for use in the disclosed methods comprise nanoparticles. In some embodiments, the nanoparticles have a maximum dimension in the range from about 5 nm to about 5000 nm. This includes embodiments in which the nanoparticles have a maximum dimension in the range from about 10 nm to about 4000 nm; from about 20 nm to about 3000 nm; from about 50 nm to about 2000 nm; from about 100 nm to about 1000 pm; and from about 200 nm to about 500 nm. Both spherical and nonspherical (e.g., rods, tubes, fibers) nanoparticles may be used.

In embodiments, nanoparticles may be composed of semiconductors. Semiconductors may be intrinsic or extrinsic. Intrinsic semiconductors have pure and undoped crystals, where examples include, but are not limited to, Examples include silicon and germanium. Extrinsic semiconductors are doped with small amounts of impurities to either increase the electron or hole concentration. For example, quadravalent Si can be doped with small amounts of pentavalent arsenic impurities so that the electron concentration is larger than the hole concentration which is referred to as an n-type semiconductor. In addition, Si can be doped with trivalent boron impurities to increase the hole concentration above the electron concentration, which is referred to as a p-type semiconductor. It will be apparent to one of skill in the art that such semiconductors as disclosed may be used in various applications, to include diodes, solar cells and the like.

In embodiments, materials that may be used with the solutions and the methods as disclosed herein include, but are not limited to, elemental semiconductors, such as Group IV elements Si, Ge, C and alloyed semiconductors, including Group II-V (e.g., gallium-arsenide) and Group II-VI (e.g., cadmium-telluride) or oxide materials, including zinc oxide and indium tin oxide.

In embodiments, the nanoparticles may be composed of Si.

Various amounts of nanoparticles may be used. In embodiments, the amount of the nanoparticles in the solution is sufficient to provide a nanoparticle film having a desired area and desired thickness. In some embodiments, the amount of the nanoparticles in the solution is in the range from about 0.00005 g/mL to about 0.5 g/mL, where grams refers to the weight of the nanoparticles added to the solution and mL refers to the volume of the solution to which the nanoparticles are added. This includes embodiments in which the amount of the nanoparticles in the solution in is the range from about 0.0005 g/mL to about 0.05 g/mL, from about 0.0001 g/mL to about 0.01 g/mL, from about 0.0001 g/mL to about 0.005 g/mL, or from about 0.001 g/mL to about 0.05 g/mL.

### Methods

Some of the disclosed methods comprise exposing a substrate to any of the solutions described above and applying an electric field to the solution, whereby a nanoparticle film is deposited on the substrate via electrophoretic deposition. Apparatuses for electrophoretic deposition are known and typically comprise a vessel to hold the solution and electrodes and a power supply to generate an electric field in the solution. An exemplary apparatus 100 has been described above with reference to FIG. 2. The electric field is generated in the solution 106 by supplying a voltage or current via the power supply 110 to the spaced apart electrode 102 and substrate 104 acting as a counter electrode. Various magnitudes of voltage or current may be used. For example, a voltage of about 1000 V may be used or voltages in the range of from about 0 V to about 600 V or a current in the range of from about 0 Amps to about 10 Amps may be used. The voltage or current used may be direct, alternating, pulsed or ramped. If applicable (e.g., for alternating voltage or current), various frequencies of the applied voltage or current may be used. For example, a frequency in the range of from about 0 Hz to about 100 kHz may be used. Various distances between the electrode and substrate (counter electrode) may be used. For example, a distance in the range of from about 1 mm to about 100 mm may be used. Various deposition times (i.e., the length of time the electric field is applied) may be used. For example, deposition times in the range of from about 1 s to about 100 min or from about 3 s to about 10 min may be used. The characteristics of the applied electric field, the distance between electrodes and the deposition time may be adjusted to modify the properties of the nanoparticle films thus deposited.

Various conductive substrates may be used in the disclosed methods based on the technique of electrophoretic deposition. Exemplary conductive substrates include glass coated with a transparent conducting oxide, such as indium tin oxide (ITO), stainless steel or other metals, and conductive polymers.

The deposited nanoparticle films may be evaluated by standard methods. Visual inspection may be used to evaluate the uniformity of the film, its overall morphology and its adhesion to the underlying substrate. Microscopic structure and surface roughness may be evaluated using scanning electron microscopy (SEM) and atomic force microscopy (AFM).

In embodiments, a process for depositing Si nanoparticle-based films is disclosed using a solution comprising alkane/alcohol solvent combinations, such that the nanoparticles do not settle and remain mono-dispersed, in conjunction with an EPD method.

In a further related aspect, the nanoparticles may be deposited at a deposition rate of about 1 to about 10 microns/hr, where said nanoparticles deposit with high uniformity without film defects such as cracking or peeling. The deposited films as disclosed herein show excellent adhesion to the substrate and are not damaged when handled.

As disclosed herein, the morphology and thickness of the deposited film is greatly dependent on applied voltage, deposition time, particle size, nanoparticle concentration, and substrate conductivity. The characteristics of the deposited film may be controlled through the adjustment of supplied voltage and deposition times. In embodiments, different applied voltages may be used along with different time durations.

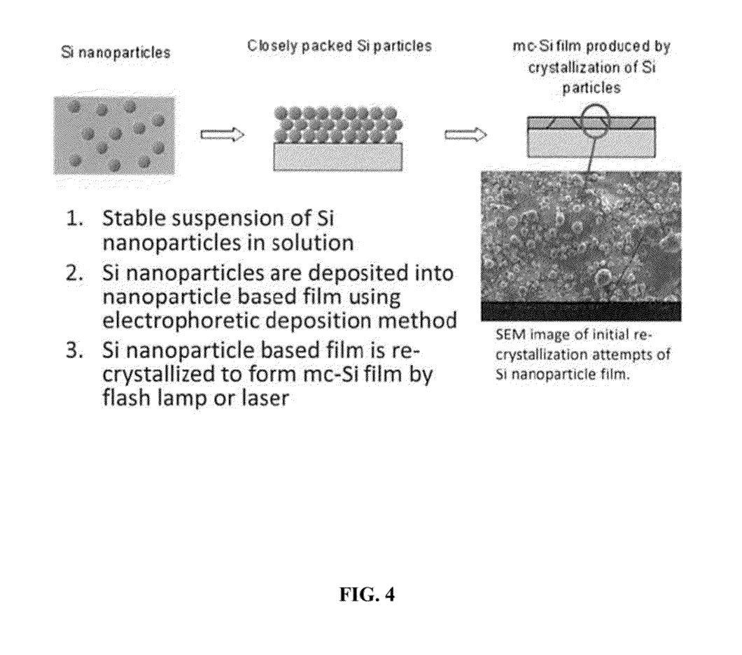

In embodiments, the Si thin films as disclosed herein may be microcrystalline Si (mc-Si) thin films for use as solar absorbers and in thin film transistors (TFTs). In one aspect, displays using me-Si thin film transistors have better electrical and optical properties compared to conventional amorphous Si-TFTs. In another aspect, mc-Si solar cell absorbers have higher stabilities and efficiencies than conventional amorphous Si absorbers. Typical low-cost substrates (e.g., glass, plastics and the like) exhibit low-melting temperatures and current mc-Si methods are carried out at high temperatures, in contrast to the production method as disclosed herein. Further, current production methods are extremely slow. In embodiments, mc-Si may be formed on low-cost substrates at low-temperatures using shorter production times (see, e.g., FIG. 4).

In other embodiments, the thin films may be Ge thin films, including microcrystalline Ge.

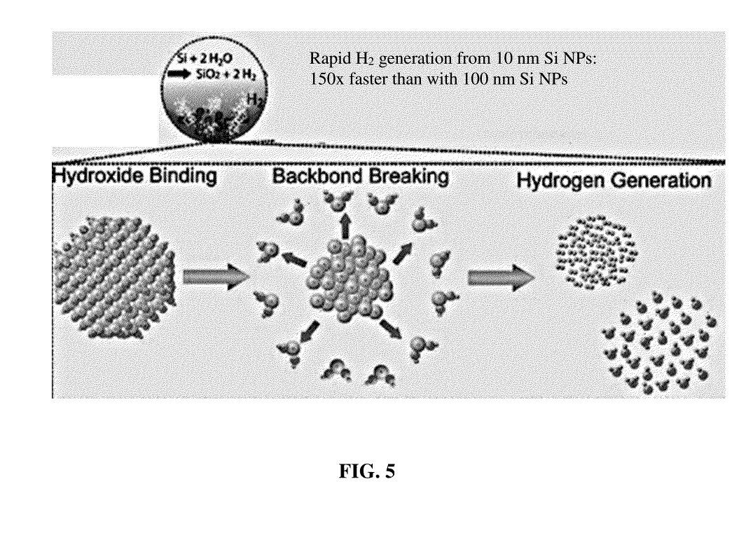

In embodiments, the Si nanoparticles may be consumed by water for on demand hydrogen fuel generation. In one aspect, the Si nanoparticles may be used by fuels cells to produce electricity for portable applications (see e.g., FIG. 5).

In one aspect, LEDs can replace fluorescent lamps as the backlight source for small LCDs such as cell phones, hand held devices, medical monitors and automotive displays. The advantage of using LEDs is their low price, small size and low energy consumption. The disadvantage of LEDs is their relatively low brightness. In embodiments, Si nanoparticles (e.g., 5 nm diameter) soften the blue light emitted by LEDs, creating white light that more closely resembles sunlight. Conventionally, this is accomplished using rare-earth elements, such as phosphor, which elements are expensive and hazardous to extract and process. On the contrary, Si is abundant and non-toxic.

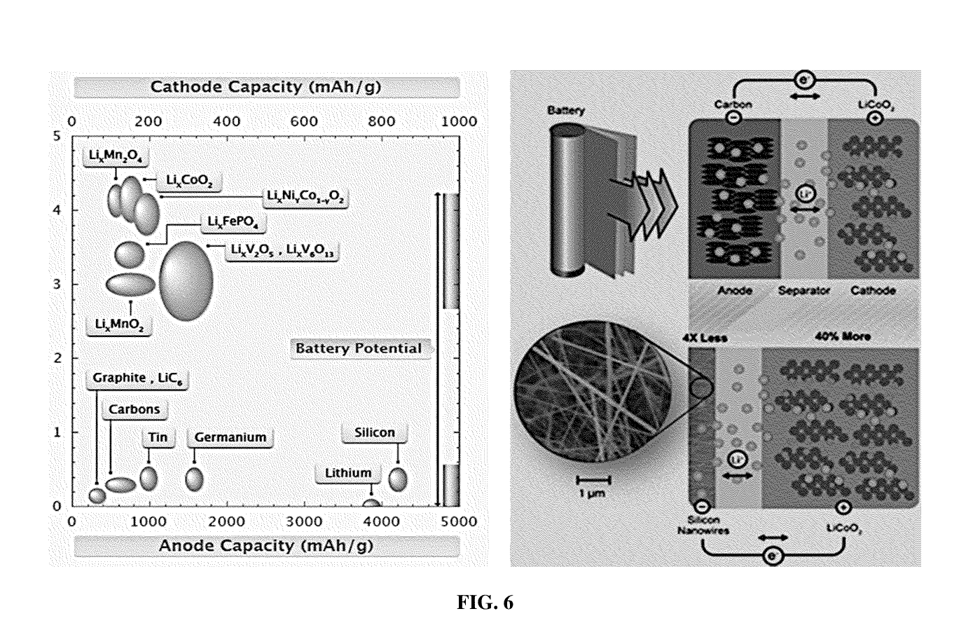

In embodiments, the Si nanoparticles may be used to form Si anodes for Li ion batteries (see FIG. 6). In one aspect, using Si nanoparticles/wires instead of conventionally used graphite results in 3 to 10 times increased energy density for Li ion batteries.

In embodiments, the Si nanoparticles of the present disclosure may be used as quantum energy devices by exploiting the unique piezoelectric stress of Si nanoparticle (<10 nm) films.

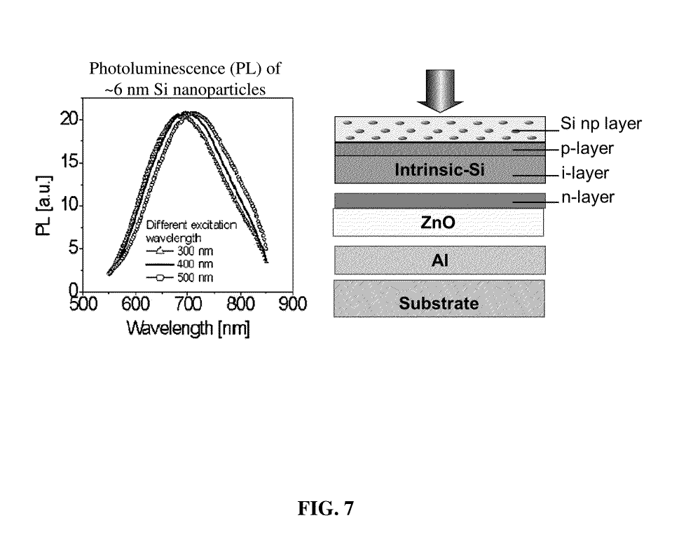

In embodiments, Si nanoparticles as disclosed herein may be used in photon down shifting (see FIG. 7, right). Si nanoparticles (<10 nm) can absorb UV light and photoluminesce (PL) visible light (FIG. 7, left). Further, the band gap of Si nanoparticles increases as diameter decreases. Thus, solar cells comprising Si nanoparticles as disclosed herein can utilize more of the sun's spectrum (UV portion), where efficiency gains may be low. Moreover, such Si nanoparticle comprising devices may be used in display materials that are sensitive to UV light.

The following examples are intended to illustrate but not limit the invention.

### EXAMPLES

### Example 1

### EPD Deposition of Dielectric Nanoparticles onto ITO Coated Glass Substrate

### Materials

Solution: 20 ml decane, 1 ml hexanol, about 1 mg Si nanoparticles. The solution was stirred and then sonicated for up to 1 hour (typically 30 minutes).

EPD set-up: ITO coated glass electrodes (approximately 1 in×1 in) spaced about 2 cm part.

### Method

EPD conditions: voltage<600 V, up to about 1 hour. Longer times result in thicker films. Films were allowed to air dry with or without voltage remaining on until dry. EPD may be repeated multiple times using the same electrodes/substrate.

Solutions comprising Si nanoparticles were prepared by adding nanoparticles to a solution containing an aprotic, non-polar organic solvent and a protic, polar organic solvent. Two ITO (indium tin oxide) coated glass electrodes, serving as an anode and a cathode, were held by alligator clips connected to a power supply. Prior to using the substrates, they were thoroughly rinsed with distilled water and acetone, sonicated with both individually, and then dried at room temperature. An EPD bath was prepared by mixing the nanoparticle powder and the solution recited above. The mixture was stirred then ultrasonicated for up to 60 minutes to disperse the particles.

When the solution was prepared, the substrates were dipped in the solution. The EPD process was conducted by applying a voltage across the electrodes for deposition.

### Results

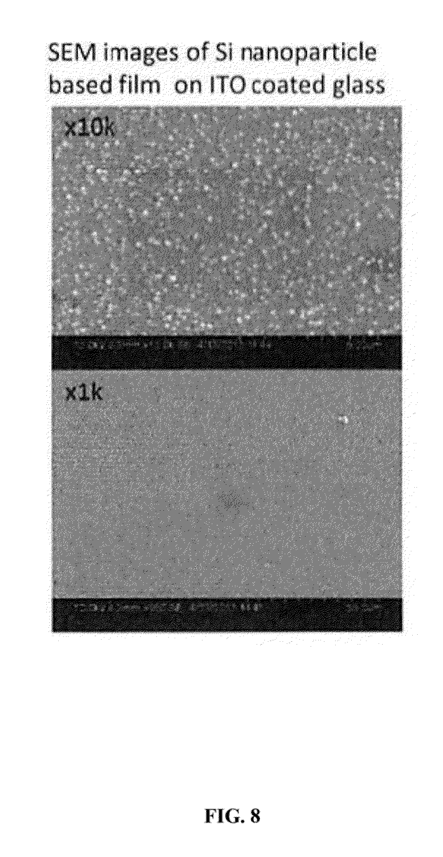

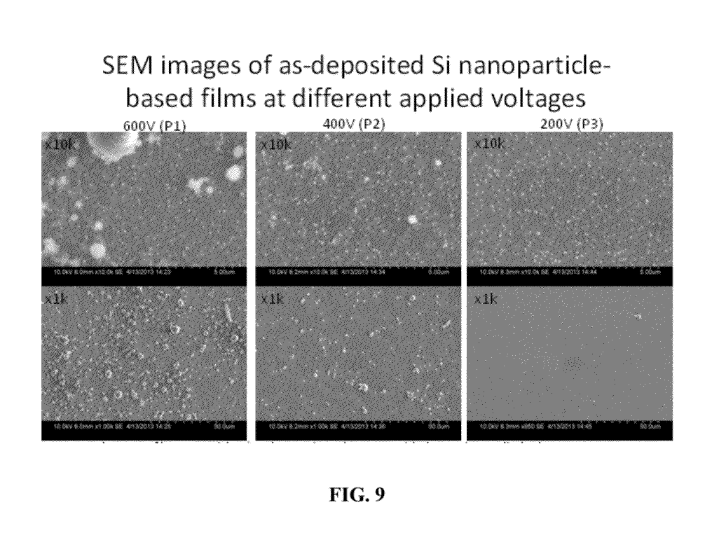

Si nanoparticles were stable in the solution for a period of hours. Use of the solution with EPD resulted in a film exhibiting uniform film quality, tight packing of the particles and controllable thickness (see FIG. 8). Higher voltage resulted in higher deposition rate (FIG. 9). Si nanoparticles deposited on both anode and cathode, though the anode had the thicker deposition. There was no measurable current (to 1 hundredth of an amp; i.e., 0.00 A). The solution became clear after deposition as the majority of particles were deposited on the substrate, with the remaining sticking to the sides of the beaker or settled at the bottom.

As may be seen from the results, a stable Si nanoparticle suspension has been developed, which suspension contains a non-aqueous solution useful for EPD without the use of salts or ionic surfactants to achieve high quality electronic films.

### Example 2

### Si Nanoparticle Suspensions

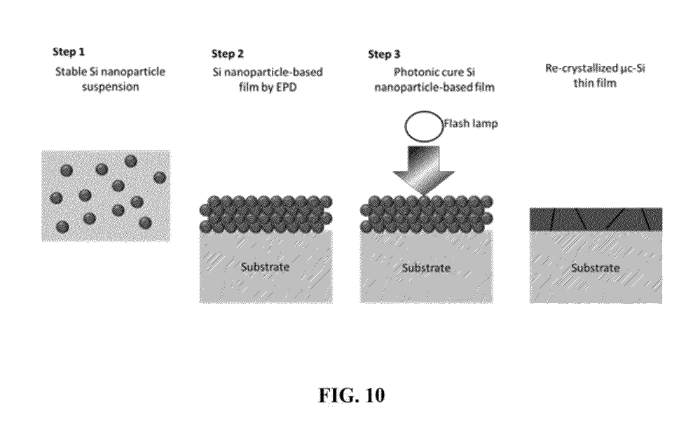

FIG. 10 shows a diagram of the three step process used to produce microcrystalline thin films: (1) prepare stable Si nanoparticle suspensions; (2) produce Si nanoparticle-based films by electrophoretic deposition; and (3) re-crystallize Si-nanoparticle-based films by photonic curing. The Si nanoparticle suspension compositions are summarized in Table 1.

TABLE 1
Si Nanoparticle Suspension Composition and Electrophoretic Deposition (EPD) Parameters.

| Suspension | Si | | EPD Conditions | | | |
|---|---|---|---|---|---|---|
| # | Nanoparticle | Solvents | Voltage (V) | Time (min) | Anode (+) | Cathode (−) |
| S1 | 1 mg (130 | 20 ml | 4000 | 2 | ITO³ | ITO³ |
| | nm)¹ | decane | | | | |
| S2 | 1 mg (130 | 20 ml | 4000 | 4 | ITO³ | ITO³ |
| | nm)¹ | decane; 1 | | | | |
| | | ml hexanol | | | | |
| S3 | 1 mg (130 | 20 ml | 1000 | 20 | ITO³ | ITO³ |
| | nm)¹ | decane; 1 | | | | |
| | | ml hexanol | | | | |
| S4 | 1 mg (130 | 20 ml | 500 | 48 | ITO³ | ITO³ |
| | nm)¹ | decane; 1 | | | | |
| | | ml hexanol | | | | |
| S5 | 1 mg (130 | 20 ml | 400 | 33 | ITO³ | ITO³ |
| | nm)¹ | decane; 1 | | | | |
| | | ml hexanol | | | | |
| S6 | 1 mg (130 | 20 ml | 200 | 50 | ITO³ | ITO³ |
| | nm)¹ | decane; 1 | | | | |
| | | ml hexanol | | | | |
| S7 | 90 mg | 10 ml | 200 | 1 | Si⁴ | Al⁵ |
| | (20~50 nm)² | hexanol; 10 | | | | |
| | | ml acetone | | | | |
| S8 | 90 mg | 10 ml | 200 | 1 | ITO⁶ | Al⁵ |
| | (20~50 nm)² | hexanol; 10 | | | | |
| | | ml acetone | | | | |

¹Si nanoparticles purchased from American Elements (CAS 7440-21-3): 99.9% purity; 130 nm average size; yellow-brown powder.
²Nanocrystalline Si nanoparticles purchased from STREM Chemical (CAS 7440-21-3); 97% purity; 20~50 nm average size; brown powder.
³Indium tin oxide (ITO) coated glass received from Wintek Electro-Optical: 1 inch × 0.5 inch; 12.9 Ω/sq.
⁴Purchased p-type Si wafer (100); 1 inch × 0.5 inch, two side polished; 10~20 Ω cm; 525 ± 25 μm thick.
⁵Single-side polished 6061 A1 purchased from McMaster-Carr, 1 inch × 1 inch.
⁶Purchased ITO coated glass; 1 inch × 0.5 inch; 6.4 Ω/sq.

Physical properties of the suspension solvents are shown in Table 2.

| | Boil- | Vapor | | | Conduc- | Rela- |
|---|---|---|---|---|---|---|
| | ing | Pres- | | Viscos- | tivity | tive |
| | Point | sure | Density | ity | (ohms⁻¹ | Permit- |
| Solvent | (° C. ) | (mmHg) | (g/cm³) | (cP) | cm⁻¹) | tivity |
| Water | 100 | 23.8 | 0.997 | 0.89 | 6 × 10⁻⁸ | 78.39 |
| MeOH | 64.5 | 177 | 0.7864 | 0.551 | 1.5 × 10⁻⁹ | 32.7 |
| EtOH | 78.3 | 59 | 0.7849 | 1.083 | 1.4 × 10⁻⁹ | 24.6 |
| Propanol | 97.2 | 21 | 0.7996 | 1.943 | 9 × 10⁻⁹ | 20.5 |
| Hexanol | 156 | 1 | 0.814 | | | 13.3 |
| Acetone | 56.1 | 231 | 0.7844 | 0.303 | 5 × 10⁻⁹ | 20.6 |
| Hexane | 68.7 | 151.3 | 0.6548 | 0.294 | <10⁻¹⁶ | 1.88 |
| Decane | 174 | 1 | 0.73 | 1.16 | | 2 |

The Si nanoparticles were dispersed in the solvent mixture by sonication for at least 10 minutes so that the suspension was a uniform brown color. Alkane suspensions were chosen to prevent electrochemical reactions, such as bubbling, from occurring at the EPD electrodes, where bubbles can decrease the nanoparticle-based film quality. Higher molecular weight alkanes (e.g., decane) were chosen over lower molecular weight alkanes (e.g., hexane) due to lower vapor pressure and hence lower evaporation rate (Table 2). Uniform Si nanoparticle-based films across the entire electrode (substrate) were able to be electrophoretically deposited when alkane suspensions were used and correlated with no measurable current. In comparison, when polar suspensions (i.e., EtOH, propanol and the like) were used for EPD, the Si nanoparticles were observed to predominantly deposit on the electrode edges, the ITO cathode was reduced/oxidized turning a dark brown color, and there was a measurable current (μA) possibly due to the high 10⁻⁹) conductivity (Table 2). The steady-state (no external field) stability, as determined by the time that sedimentation occurred by visual observation and the suspension turned from brown to clear, was improved from a few minutes to a few hours with the addition of alcohol. Further, alcohols with moderate molecular weights (e.g., hexanol) were shown to have higher stability compared to lower (e.g., propanol, butanol and the like) or higher (heptanol, octanol) molecular weights, which, while not being bound by theory, may be due to a balance between the polar (hydrogen) and non-polar (van der Waal) interactions such that one did not dominate over the other.

The Si nanoparticle-based films were photonic cured using a Novacentrix PulseForge 3300 system located at Wintek Electro-Optical (Ann Arbor, Mich.). The photonic curing processing parameters consist of pre-heating the sample to 350° C. and using one flash lamp pulse driven by 450 to 650 V for 115 to 500 μs to produce approximately 4500 to 7500 mJ/cm² of energy.

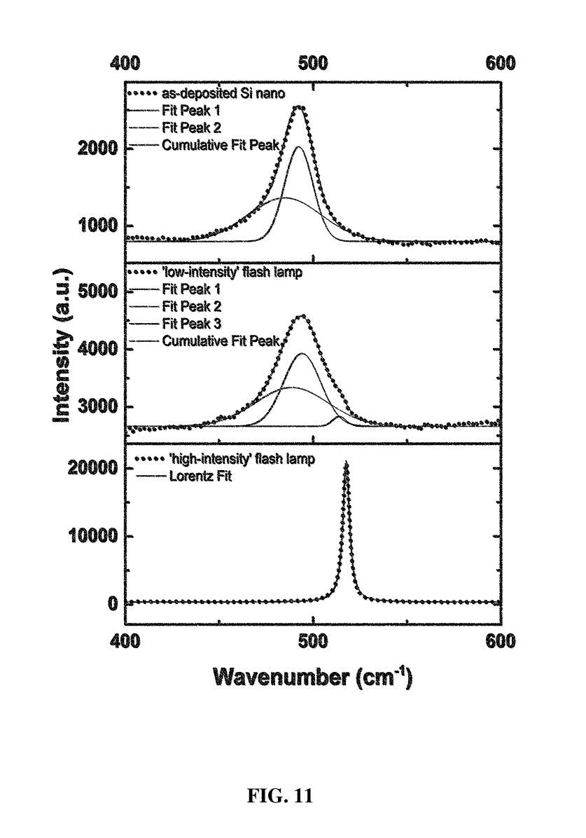

FIG. 11 shows Raman spectra of Si nanoparticle films on ITO substrate produced using the procedure above, with and without photonic curing. FIG. 1(a) shows the as-deposited Si nanoparticle-based film with de-convoluted Gaussian fitting peaks at 485 cm⁻¹ and 492 cm⁻¹ signifying amorphous and defective crystalline Si phases, respectively, the defective crystalline phase could be attributed to crystalline grains in the nanoparticle agreeing with the manufacturer's “nanocrystalline” labeling where the grain boundaries were defective (dangling bonds), or could be due to the high surface area of the nanoparticle-based film. The low-energy photonic curing Raman spectrum of FIG. 11(b) shows Gaussian fitting peaks at 494 cm⁻¹, 489 cm⁻¹, and 514 cm⁻¹, where the two former peaks with relatively larger intensity, and while not being bound by theory, this suggests that the film remained mostly unchanged in terms of amorphous and defect crystalline phases, but the smaller intensity latter peak suggests, again not to be bound by theory, some (i.e., portions) of the Si globules had higher crystallinity and less defective phases.

The high energy photonic curing Raman spectrum of FIG. 11(c) shows Lorentz fitting peak at 518 cm⁻¹ suggesting (while not being bound by theory) that Si globules were comprised of low-defect, high crystallinity Si. The Raman peak shift of photonic cured Si globules (518 cm⁻¹) from 520 cm⁻¹ for crystalline Si (wafer) can be attributed to the existence of nanometer sized features or to the influence of the defective surface, where the globule film's surface area to volume (bulk) ratio was much larger than a conventional Si thin film or Si wafer.

Although the invention has been described with reference to the above examples, it will be understood that modifications and variations are encompassed within the spirit and scope of the invention. Accordingly, the invention is limited only by the following claims.

We claim herein:

1. A composition consisting essentially of:
an organic solvent selected from the group consisting of an aprotic, non-polar organic solvent; a protic, polar organic solvent; a ketone or a combination thereof; and
a plurality of nanoparticles,
wherein the plurality of nanoparticles comprise an elemental semiconductor, alloyed semiconductor, or oxide.

2. The composition of claim 1, wherein the elemental semiconductor is Si or Ge.

3. The composition of claim 1, wherein said aprotic, non-polar solvent has the general structure as set forth in Formula I:
(CₙH₂ₙ₊₂₋₂ᵣ) (Formula I),
wherein n is an integer from 6 to 20, and r, the number of ring structures, is an integer from 0 to 3,
and wherein the protic, polar organic solvent has the general structure as set forth in Formula II:
(CₙH₂ₙ₊₂₋ₘ₋₂ᵣ(OH)ₘ) (Formula II),
wherein n is an integer from 1 to 20, m is an integer from 1 to 10, and r, the number of ring structures, is an integer from 0-3,
and wherein the ketone organic solvent has the general structure as set forth in Formula III:
(CnH₂ₙ₊₂₋₂ᵣ(C═O)ₘ) (Formula III),
wherein n is an integer from 1 to 30, m is an integer from 1 to 5 and r, the number of ring structures, is an integer from 0 to 3.

4. The composition of claim 1, wherein the aprotic, non-polar organic solvent is an alkane and exhibits a dielectric constant of less than about 10.

5. The composition of claim 1, wherein the protic, polar organic solvent is selected from the group consisting of methanol, ethanol, propanol, butanol, pentanol, hexanol, heptanol, octanol, nonanol, and decanol.

6. The composition of claim 1, wherein the ketone is symmetrical, asymmetrical, a di-ketone, an unsaturated ketone, or a cyclic ketone.

7. The composition of claim 1, wherein the organic solvent comprises decane and hexanol.

8. The composition of claim 1, wherein the organic solvent comprises hexanol and acetone.

9. A method of depositing a plurality of Si or Ge nanoparticles on a substrate comprising:
adding the composition of claim 1 to a vessel;
placing two electrodes into the composition, whereby said electrodes serve as an anode and a cathode in electric communication with a power supply, and wherein at least one of the electrodes comprises the substrate; and
applying voltage across the electrodes for a sufficient time to coat said substrate with the Si or Ge nanoparticles.

10. The method of claim 9, wherein the ratio of an aprotic, non-polar organic solvent to a protic, polar organic solvent is about 95:5, or wherein the ratio of ketone to protic, polar organic solvent is 1:1, and wherein the plurality of Si or Ge nanoparticles are present at between about 0.00005 g/mL to about 0.5 g/mL.

11. The method of claim 9, further comprising re-crystallizing the Si or Ge nanoparticles by photonic curing.

12. The method of claim 9, wherein the aprotic, non-polar organic solvent is an alkane and exhibits a dielectric constant of less than about 10.

13. The method of claim 9, wherein the protic, polar organic solvent is selected from the group consisting of methanol, ethanol, propanol, butanol, pentanol, hexanol, heptanol, octanol, nonanol, and decanol.

14. The method of claim 9, wherein the ketone is symmetrical, asymmetrical, a di-ketone, an unsaturated ketone, or a cyclic ketone.

15. The method of claim 9, wherein the organic solvent comprises decane and hexanol.

16. The method of claim 9, wherein the organic solvent comprises hexanol and acetone.

17. A Si or Ge nanoparticle-based film produced by the method of claim 9.

18. The film of claim 17, wherein a surface of the film comprising the nanoparticles is devoid of agglomerations.

19. The film of claim 18, wherein said agglomerations comprise clumps of nanoparticles>about 2× or 3× the diameter of a single nanoparticle in an area of about 15 μm×10 μm at a magnification of 10K as visualized under a scanning electron microscope (SEM).

20. The film of claim 19, wherein said agglomerations have a diameter of between about 2 nm to about 500 nm.
